(19) United States
(12) Patent Application Publication
(10) Pub. No.: US 2026/0323806 A1
(43) Pub. Date: Oct. 15, 2026

(54) TARGET SUPPLY METHOD AND ELECTRONIC DEVICE MANUFACTURING METHOD

(71) Applicant: Gigaphoton Inc., Tochigi (JP)

(72) Inventor: Masaki NAKANO, Tochigi (JP)

(73) Assignee: Gigaphoton Inc., Tochigi (JP)

(21) Appl. No.: 19/561,674

(22) Filed: Mar. 10, 2026

(30) Foreign Application Priority Data
Apr. 15, 2025 (JP) 2025-066758

(51) Int. Cl. H05G 2/00; G01N 21/956; G03F 1/22; G03F 7/00; G03F 7/20

(52) U.S. Cl. CPC H05G 2/0027; G01N 21/956; G03F 1/22; G03F 7/2004; G03F 7/70033; G01N 2021/95676

(57) ABSTRACT

A target supply method into a chamber from a target generator, including a tank storing a target, a nozzle being in communication with inside the tank and discharging the molten target, and a filter arranged inside the tank or the nozzle, includes a first step of stopping supplying the target into the chamber; a second step of evacuating the tank to set pressure in the tank to pressure of vacuum of 10⁻⁵ Pa or higher and 638 Pa or lower; a third step of decreasing temperature of the tank to be lower than a melting point of the target while maintaining the pressure of vacuum; a fourth step of increasing the temperature to be equal to or higher than the melting point, after the third step, while the pressure of vacuum is maintained; and a fifth step of resupplying the target, melted in the fourth step, into the chamber.

### CROSS-REFERENCE TO RELATED APPLICATIONS

The present application claims the benefit of Japanese Patent Application No. 2025-066758, filed on Apr. 15, 2025, the entire contents of which are hereby incorporated by reference.

### BACKGROUND

### 1. Technical Field

The present disclosure relates to a target supply method and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2014/0042653
Patent Document 2: US Patent Application Publication No. 2019/0237303

### SUMMARY

An aspect of the present disclosure provides a target supply method from a target generator into a chamber, the target generator including a tank configured to store a target, a nozzle being in communication with inside the tank and configured to discharge the target in a molten state, and a filter arranged inside the tank or inside the nozzle. The target supply method includes a first step of stopping supplying the target into the chamber; a second step of evacuating the tank to set a pressure in the tank to a pressure of vacuum equal to or higher than 10⁻⁵ Pa and lower than 638 Pa; a third step of decreasing a temperature of the tank to be lower than a melting point of the target while maintaining the pressure vacuum; a of fourth step of increasing the temperature of the tank to be equal to or higher than the melting point of the target, after the third step, while the pressure of vacuum is maintained; and a fifth step of resupplying the target, melted in the fourth step, into the chamber.

An electronic device manufacturing method according to an aspect of the present disclosure includes generating extreme ultraviolet light by irradiating a target, resupplied into a chamber, with pulse laser light, using an extreme ultraviolet light system; outputting the extreme ultraviolet light to an exposure apparatus; and exposing a photosensitive substrate to the extreme ultraviolet light in the exposure apparatus to manufacture an electronic device. Here, the extreme ultraviolet light system includes the chamber, a target generator configured to supply the target into the chamber, and a laser device configured to output the pulse laser light. The target generator includes a tank configured to store the target, a nozzle being in communication with inside the tank and configured to discharge the target in a molten state, and a filter arranged inside the tank or inside the nozzle. The target i resupplied into the chamber through steps of stopping supplying the target into the chamber; evacuating the tank to set a pressure in the tank to a pressure of vacuum equal to or higher than 10⁻⁵ Pa and lower than 638 Pa; decreasing a temperature of the tank to be lower than a melting point of the target while maintaining the pressure of vacuum; increasing the temperature of the tank to be equal to or higher than the melting point of the target, after the temperature decreasing, while the pressure of vacuum is maintained; and resupplying the target, melted with the temperature increasing, into the chamber.

An electronic device manufacturing method according to an aspect of the present disclosure includes generating extreme light ultraviolet by irradiating a target, resupplied into a chamber, with pulse laser light; inspecting a defect of a mask by irradiating the mask with the extreme ultraviolet light; selecting a mask using a result of the inspection; and exposing and transferring a pattern formed on the selected mask onto a photosensitive substrate. Here, the extreme ultraviolet light system includes the chamber, a target generator configured to supply the target into the chamber, and a laser device configured to output the pulse laser light. The target generator includes a tank configured to store the target, a nozzle being in communication with inside the tank and configured to discharge the target in a molten state, and a filter arranged inside the tank or inside the nozzle. The target is resupplied into the chamber through steps of stopping supplying the target into the chamber; evacuating the tank to set a pressure in the tank to a pressure of vacuum equal to or higher than 10⁻⁵ Pa and lower than 638 Pa; decreasing a temperature of the tank to be lower than a melting point of the target while maintaining the pressure of vacuum; increasing the temperature of the tank to be equal to or higher than the melting point of the target, after the temperature decreasing, while the pressure of vacuum is maintained; and resupplying the target, melted with the temperature increasing, into the chamber.

### BRIEF DESCRIPTION OF THE DRAWINGS

Embodiments of the present disclosure will be described below merely as examples with reference to the accompanying drawings.

FIG. 1 is a diagram schematically showing a configuration example of an LPP type EUV light generation system.

FIG. 2 is a diagram schematically showing the configuration of an EUV light generation apparatus according to a comparative example.

FIG. 3 is a flowchart of a resupply process according to the comparative example.

FIG. 4 is a diagram schematically showing a state in a tank in which a target is solidified.

FIG. 5 is a partially enlarged diagram of a portion of a filter shown in FIG. 4.

FIG. 6 is a flowchart of the resupply process to which a target supply method according to a first embodiment is applied.

FIG. 7 is a graph showing the relationship between a pressure in the tank and a velocity ratio of the target during evacuation when a standard filter is used.

FIG. 8 is a graph showing the relationship between a pressure in the tank and a velocity ratio of the target during evacuation when a high performance filter is used.

FIG. 9 is a graph showing the relationship between a pressure in the tank and a velocity ratio of the target during evacuation when an ultra-high performance filter is used.

FIG. 10 is a flowchart of the resupply process to which the target supply method according to a second embodiment is applied.

FIG. 11 is a diagram schematically showing the configuration of the EUV light generation apparatus according to a third embodiment.

FIG. 12 is a flowchart of the resupply process to which the target supply method according to the third embodiment is applied.

FIG. 13 is a flowchart of the resupply process to which the target supply method according to a modification of the third embodiment is applied.

FIG. 14 is a diagram schematically showing the configuration of an exposure apparatus connected to the EUV light generation system.

FIG. 15 is a diagram schematically showing the configuration of an inspection apparatus connected to the EUV light generation system.

### DESCRIPTION OF EMBODIMENTS

### <Contents>

1. Overall description of EUV light generation system
   1.1 Configuration
   1.2 Operation
2. Explanation of EUV light generation apparatus according to comparative example
   2.1 Configuration
   2.2 Operation
   2.3 Problem
3. First Embodiment
   3.1 Configuration
   3.2 Operation
   3.3 Effect
4. Second Embodiment
   4.1 Configuration
   4.2 Operation
   4.3 Effect
5. Third Embodiment
   5.1 Configuration
   5.2 Operation
   5.3 Effect
   5.4 Modification
      5.4.1 Configuration
      5.4.2 Operation
      5.4.3 Effect
6. Electronic device manufacturing method
7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overall Description of EUV Light Generation System

### 1.1 Configuration

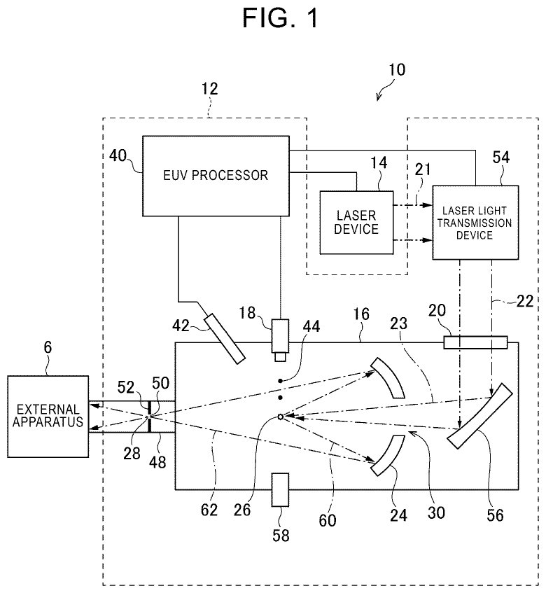

FIG. 1 is a diagram schematically showing a configuration example of an LPP type EUV light generation system 10. An EUV light generation apparatus 12 is used together with a laser device 14. In the present disclosure, a system including the EUV light generation apparatus 12 and the laser device 14 is referred to as the EUV light is an generation system 10. The expression “EUV light” abbreviation for “extreme ultraviolet light”. The EUV light generation apparatus 12 includes a chamber 16 and a target supply unit 18.

The chamber 16 is a sealable container. The target supply unit 18 supplies a target 44 into the chamber 16. The target 44 may include tin, terbium, gadolinium, lithium, xenon, or a combination of any two or more thereof.

A through hole is formed in a wall of the chamber 16. The through hole is blocked by a window 20 through which pulse laser light 22 output from the laser device 14 passes. An EUV light concentrating mirror 24 having a spheroidal reflection surface is arranged in the chamber 16. The EUV light concentrating mirror 24 has a first focal point and a second focal point. A multilayer reflection film in which molybdenum and silicon are alternately stacked is formed on a surface of the EUV light concentrating mirror 24. The EUV light concentrating mirror 24 may be arranged so that the first focal point is located in a plasma generation region 26 and the second focal point is located at an intermediate focal point 28. A through hole 30 is formed at the center of the EUV light concentrating mirror 24, and pulse laser light 23 passes through the through hole 30.

The EUV light generation apparatus 12 includes an EUV processor 40, a target sensor 42, and the like. The target sensor 42 detects at least one of the presence, trajectory, position, and velocity of the target 44. The target sensor 42 may have an imaging function.

Further, the EUV light generation apparatus 12 includes a connection portion 48 providing communication between the inside of the chamber 16 and the inside of an external apparatus 6. A wall 52 in which an aperture 50 is formed is provided in the connection portion 48. The wall 52 is arranged so that the aperture 50 is located at the second focal point of the EUV light concentrating mirror 24.

Further, the EUV light generation apparatus 12 includes a laser light transmission device 54, a laser light concentrating mirror 56, a target receiver 58 for collecting the target 44, and the like. The laser light transmission device 54 includes an optical element for defining a transmission state of laser light, and an actuator for adjusting the position, posture, and the like of the optical element.

### 1.2 Operation

Operation of the LPP type EUV light generation system 10 will be described with reference to FIG. 1. Pulse laser light 21 output from the laser device 14 enters, via the laser light transmission device 54, the chamber 16 through the window 20 as the pulse laser light 22. The pulse laser light 22 travels along a laser light path in the chamber 16, is reflected by the laser light concentrating mirror 56, and is radiated to the target 44 as the pulse laser light 23.

The target supply unit 18 outputs the target 44 formed of a target substance toward the plasma generation region 26 in the chamber 16. The target 44 is irradiated with the pulse laser light 23. The target 44 irradiated with the pulse laser light 23 is turned into plasma, and radiation light 60 is radiated from the plasma. EUV light 62 contained in the radiation light 60 is selectively reflected by the EUV light concentrating mirror 24. The EUV light 62 reflected by the EUV light concentrating mirror 24 is concentrated at the intermediate focal point 28 and output to the external apparatus 6. Here, one target 44 may be irradiated with a plurality of pulses included in the pulse laser light 23. The external apparatus 6 may be, for example, an exposure apparatus or an inspection apparatus.

The EUV processor 40 controls the entire EUV light generation system 10. The EUV processor 40 processes a detection result of the target sensor 42. Based on the detection result of the target sensor 42, the EUV processor 40 may control timing at which the target 44 is output, an output direction of the target 44, and the like. Further, the EUV processor 40 may control oscillation timing of the laser device 14, the travel direction of the pulse laser light 22, concentration position of the pulse laser light 23, and the like. The above-described various kinds of control are merely examples, and other control may be added as necessary.

The processor such as the EUV processor 40 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 2. Explanation of EUV Light Generation Apparatus According to Comparative Example

### 2.1 Configuration

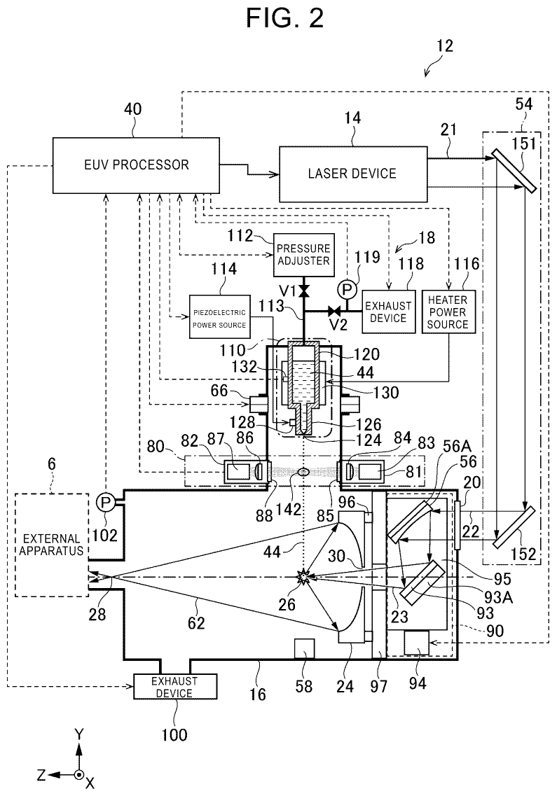

FIG. 2 is a diagram schematically showing the configuration of an EUV light generation apparatus 12 according to a comparative example. The comparative example of the present disclosure is an example recognized by the applicant as known only by the applicant, and is not a publicly known example admitted by the applicant.

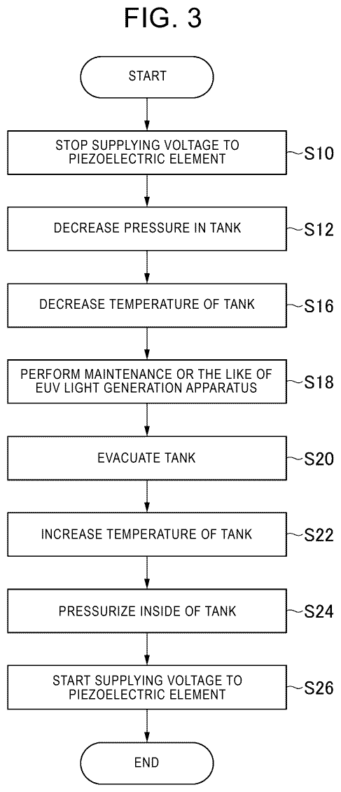

In FIG. 2, XYZ orthogonal coordinate axes are introduced for convenience of explanation regarding directions. The direction in which the EUV light 62 is output from the chamber 16 toward the external apparatus 6 is defined as a Z-axis direction. The X axis and the Y axis are orthogonal to the Z axis and are orthogonal to each other. The center axis direction of a nozzle 126 for outputting the target 44 is defined as a Y-axis direction. The Y-axis direction is the trajectory direction of a droplet. A direction perpendicular to the paper surface of FIG. 2 is defined as an X-axis direction. In FIG. 3 and subsequent drawings, the same coordinate axes as those introduced in FIG. 2 are used.

In addition to the configuration shown in FIG. 1, the chamber 16 includes a stage 66, a timing sensor 80, a laser light concentrating optical system 90, the target receiver 58, an exhaust device 100, and a pressure sensor 102. The stage 66, the timing sensor 80, a laser light manipulator 94 of the laser light concentrating optical system 90, the exhaust device 100, and the pressure sensor 102 are connected to the EUV processor 40.

The target supply unit 18 includes a target generator 110, a pressure adjuster 112, a piezoelectric power source 114, a heater power source 116, an exhaust device 118, and a pressure sensor 119. Each of the pressure adjuster 112, the piezoelectric power source 114, the heater power source 116, the exhaust device 118, and the pressure sensor 119 is connected to the EUV processor 40.

The target generator 110 includes a tank 120 that stores the target 44, the nozzle 126 including a nozzle hole 124 that communicates with the tank 120 and discharges the target 44, and a piezoelectric element 128 arranged near the nozzle 126. The target generator 110 also includes a heater 130 and a temperature sensor 132. The heater 130 and the temperature sensor 132 are arranged on the outer side surface of the tank 120.

The temperature sensor 132 is connected to the EUV processor 40. The piezoelectric power source 114 is connected to the piezoelectric element 128. The heater power source 116 is connected to the heater 130.

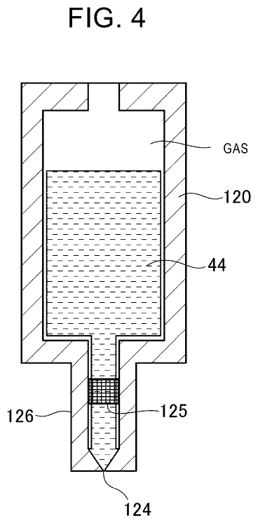

The target 44 is, for example, tin. The inside of the tank 120 is made of a material that is less likely to react with the target 44. For example, Mo, W, Ta, Al₂O₃, SiC, SiO₂, or the like can be used as the material that is less likely to react with tin, which is an example of the target 44. The tank 120 further includes a filter (not shown in FIG. 2, reference numeral 125 in FIG. 4) therein for capturing impurities in the target 44. The filter may be arranged inside the nozzle 126.

The pressure adjuster 112 is connected to the tank 120 via a pipe line 113 and a valve V1. The pressure adjuster 112 is arranged at a pipe between an inert gas supply unit (not shown) and the tank 120. The inert gas supply unit may include a gas cylinder filled with inert gas such as helium or argon. The inert gas supply unit can supply the inert gas into the tank 120 through the pressure adjuster 112. The pressure adjuster 112 may be connected to an exhaust pump (not shown). The pressure adjuster 112 includes a solenoid valve (not shown) for supplying and exhausting of gas, a pressure sensor (not shown), and the like. The pressure adjuster 112 can detect the pressure in the tank 120 using the pressure sensor. The pressure adjuster 112 can operate the exhaust pump to exhaust the gas in the tank 120.

The pressure adjuster 112 outputs a detection signal of the detected pressure to the EUV processor 40. The EUV processor 40 supplies, to the pressure adjuster 112, a control signal for controlling the operation of the pressure adjuster 112 based on the detection signal output from the pressure adjuster 112 so that the pressure in the tank 120 becomes a target pressure.

The exhaust device 118 is connected to the tank 120 via a valve V2. Each of the exhaust device 100 and the exhaust device 118 is configured of, for example, a dry pump, or a dry pump and a turbo molecular pump.

The stage 66 is arranged to be capable of moving the target generator 110 to at least a specified position in the X-Z plane based on a command from the EUV processor 40.

The timing sensor 80 includes a light source unit 81 and a light receiving unit 82. The light source unit 81 and the light receiving unit 82 are arranged so as to face each other across a target trajectory that is a travel path of the target 44 in the chamber 16.

The light source unit 81 is arranged so as to illuminate the target 44 in a detection region 142 on the target trajectory between the nozzle hole 124 of the target generator 110 and the plasma generation region 26. A light source 83 may be a monochromatic laser light source or a lamp emitting a plurality of wavelengths. The light source 83 may also include an optical fiber, which is connected to an illumination optical system 84. The illumination optical system 84 includes a light concentrating lens. The illumination optical system 84 may include a window 85. The window 85 is arranged in the wall of the chamber 16.

The light receiving unit 82 of the timing sensor 80 includes a light receiving optical system 86 and an optical sensor 87. The light receiving unit 82 is arranged so as to receive illumination light that is at least a part of the illumination light output from the light source unit 81 and has passed through the detection region 142. The light receiving optical system 86 includes a light concentrating lens. The light receiving optical system 86 may include a window 88. The window 88 is arranged in the wall of the chamber 16.

The optical sensor 87 includes one or more light receiving surfaces. The optical sensor 87 can be configured by any of a photodiode, a photodiode array, an avalanche photodiode, a photomultiplier tube, a multi-pixel photon counter, and an image intensifier. The optical sensor 87 outputs an electric signal corresponding to the amount of received light.

The window 85 of the light source unit 81 and the window 88 of the light receiving unit 82 are arranged at positions facing each other across the droplet trajectory 140. The facing direction of the light source unit 81 and the light receiving unit 82 may be perpendicular to the droplet trajectory 140 or may be non-perpendicular to the droplet trajectory 140. The timing sensor 80 is an example of the target sensor 42 shown in FIG. 1.

The laser light transmission device 54 includes a high reflection mirror 151 and a high reflection mirror 152 as optical elements for defining the travel direction of the laser light. The high reflection mirror 151 and the high reflection mirror 152 are arranged such that the pulse laser light output from the laser device 14 enters the laser light concentrating optical system 90.

The laser light concentrating optical system 90 is arranged such that the pulse laser light from the laser light transmission device 54 is concentrated in the chamber 16. The laser light concentrating optical system 90 includes the laser light concentrating mirror 56, a high reflection planar mirror 93, and the laser light manipulator 94. The laser light concentrating mirror 56 may be, for example, a high-reflection off-axis parabolic mirror. The laser light concentrating mirror 56 is held by a mirror holder 56A. The mirror holder 56A is fixed to a plate 95. The high reflection planar mirror 93 is held by a mirror holder 93A. The mirror holder 93A is fixed to the plate 95.

The laser light manipulator 94 is configured using, for example, a stage (not shown) capable of moving the plate 95 in mutually orthogonal directions of three axes of the X axis, the Y axis, and the Z axis. The laser light manipulator 94 is configured to be capable of moving the laser radiation position within the chamber 16 in the directions of the respective axes of the X axis, the Y axis, and the Z axis to a position specified by the EUV processor 40.

The EUV light concentrating mirror 24 is held by an EUV light concentrating mirror holder 96. The EUV light concentrating mirror holder 96 is fixed to a plate 97. The plate 97 is a member for holding the laser light concentrating optical system 90 and the EUV light concentrating mirror 24. The plate 97 is fixed to the inner wall of the chamber 16.

### 2.2 Operation

For starting generation of the EUV light using the EUV light generation apparatus 12, the EUV processor 40 closes the valve V1 and opens the valve V2. Then, the gas in the chamber 16 is evacuated to a pressure of high vacuum by the exhaust device 100, and the gas in the tank 120 is evacuated to a pressure of vacuum by the exhaust device 118. Thereafter, the heater 130 is driven via the heater power source 116, and the temperature of the tank 120 is raised while the temperature of the tank is monitored by the temperature sensor 132 so that the target 44 in the tank 120 has a temperature equal to or higher than the melting point thereof, and the target 44 is melted. The temperature equal to or higher than the melting point is, for example, in a range of 250° C. to 290° C. when the target 44 is tin. The pressure in the chamber 16 is measured by the pressure sensor 102. The pressure in the tank 120 may be measured by the pressure sensor 119.

After the target 44 is melted, the EUV processor 40 closes the valve V2 and opens the valve V1. Then, the inside of the tank 120 is pressurized with a gas, and the pressure adjuster 112 is controlled maintain so as to the pressurization pressure. Due to the pressurization in the tank 120, the target 44 is supplied into the chamber 16 through the nozzle hole 124. The gas pressurizing the inside of the tank 120 is, for example, an Ar gas. The pressurization pressure is, for example, equal to or higher than 3 MPa and equal to or lower than 10 MPa.

The processor 40 supplies a voltage of a predetermined waveform to the piezoelectric element 128 via the piezoelectric power source 114. As a result, the target 44 supplied into the chamber 16 through the nozzle hole 124 becomes the target 44 having a droplet shape at a predetermined cycle.

The target 44 generated at the predetermined cycle is detected by the timing sensor 80.

The EUV processor 40 outputs, to the laser device 14, a light emission trigger signal delayed by a predetermined time with respect to the detection signal of the target 44 by the timing sensor 80.

When the light emission trigger signal is input to the laser device 14, the pulse laser light is output from the laser device 14. The output pulse laser light is input to the laser light concentrating optical system 90 via the laser light transmission device 54 and the window 20.

The EUV processor 40 may control the stage 66 to move the target generator 110 such that the target 44 passes through the plasma generation region 26.

The EUV processor 40 controls the laser light manipulator 94 such that the pulse laser light is concentrated on the plasma generation region 26. The pulse laser light may be concentrated and radiated on the target 44 in the plasma generation region 26 by the laser light concentrating optical system 90. Due to the concentrated light irradiation, the EUV light 62 is generated. The EUV light 62 is cyclically generated by concentrating and radiating the pulse laser light on the target 44 supplied to the plasma generation region 26 at a predetermined cycle.

The EUV light generated from the plasma generation region 26 is concentrated by the EUV light concentrating mirror 24, concentrated at the intermediate focal point 28, and input to the external apparatus 6 such as an exposure apparatus and an inspection apparatus.

The EUV light generation apparatus 12 stops supplying the target 44 into the chamber 16 and decreases the temperature of the tank 120 to room temperature at the time of maintenance or relocation. Then, after maintenance or the like, the temperature of the tank 120 is raised, and the target 44 is supplied into the chamber 16 through the nozzle hole 124. The process from the stop of the target supply to the resumption of the supply is referred to as a resupply process.

FIG. 3 is a flowchart of the re-supply process according to the comparative example. For stopping the supply of the target 44, the EUV processor 40 stops supplying the voltage of the predetermined waveform to the piezoelectric element 128 in step S10.

Then, in step S12, the EUV processor 40 decreases the gas pressure in the tank 120 to a pressure at which the supply of the target 44 is stopped. For example, the EUV processor 40 decreases the pressure in the tank 120 to atmospheric pressure (0.1 MPa).

In step S16, the EUV processor 40 stops power supply to the heater power source 116 to decrease the temperature of the tank 120. Here, the pressure in the tank 120 is decreased to below the melting point of the target 44 at atmospheric pressure, for example, to room temperature. By stopping the power supply to the heater power source 116, the temperature of the tank 120 approaches room temperature over time. Although it is preferable to perform maintenance or the like (step S18) after the temperature of the tank 120 is decreased to room temperature, maintenance or the like may be started when the temperature is decreased to within an allowable temperature range which is not limited to room temperature. The allowable temperature range is, for example, 60 degrees or lower.

After step S16, in step S18, maintenance or the like of the EUV light generation apparatus 12 like is performed.

After completion of maintenance or the like, in step S20, the EUV processor 40 closes the valve V1 and opens the valve V2. Then, the EUV processor 40 evacuates the gas in the chamber 16 to the pressure of high vacuum using the exhaust device 100, and evacuates the gas in the tank 120 to the pressure of vacuum using the exhaust device 118.

In step S22, the EUV processor 40 drives the heater 130 via the heater power source 116, and increases the temperature of the tank 120 while monitoring the tank temperature using the temperature sensor 132 so that the target 44 in the tank 120 has a temperature equal to or higher than the melting point. In step S22, the tank 120 is heated to a temperature of, for example, 250 to 290 degrees while the pressure of vacuum is maintained.

In step S24, the EUV processor 40 closes the valve V2 and opens the valve V1. Then, the EUV processor 40 controls the pressure adjuster 112 to pressurize the inside of the tank 120 with the gas and maintain the pressurization pressure. For example, the EUV processor 40 increases the pressure in the tank 120 to 3 MPa or higher. Due to the pressurization in the tank 120, the target 44 in a jet form is supplied into the chamber 16 through the nozzle hole 124.

In step S26, the EUV processor 40 supplies a voltage of a predetermined waveform to the piezoelectric element 128 via the piezoelectric power source 114. As a result, the target 44 supplied into the chamber 16 becomes a droplet at a predetermined cycle. That is, the target 44 is resupplied into the chamber 16.

2.3 Problem

In the resupply process shown in the flowchart of FIG. 3, the temperature of the tank 120 is decreased after the pressure in the tank 120 is reduced to about 0.1 MPa (step S16). Therefore, the target 44 is decreased in temperature and solidified in a state in which the gas remains in the tank 120.

FIG. 4 is a diagram schematically showing a state in the tank 120 in which the target 44 is solidified. The target 44 shrinks when solidified. Therefore, as shown in FIG. 4, the gap formed between the target 44 and the inner surface of the tank 120 is filled with the residual gas. In the internal flow path of the nozzle 126 communicating with the tank 120 as well, the gap formed between the solidified target 44 and the inner surface of the nozzle 126 is filled with the residual gas.

The filter 125 is arranged inside the tank 120 or inside the nozzle 126. The filter 125 may be, for example, a porous filter. The filter 125 removes impurities when the target 44 passes through the filter 125.

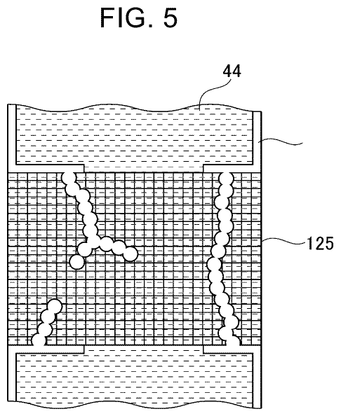

FIG. 5 is a partially enlarged diagram of a portion of the filter 125 shown in FIG. 4. As shown in FIG. 5, the target 44 in the filter 125 also shrinks when solidified, causing a gap that is to be filled with the gas.

After maintenance or the like of the EUV light generator 12 is performed, the tank 120 is evacuated (step S20). At this time, since the residual gas in the filter 125 is exhausted through the gap, the exhaust resistance increases, and exhausting cannot be performed to the pressure of vacuum. Therefore, the target 44 is melted while the gas remains in the filter 125 (step S22).

Then, the inside of the tank 120 is pressurized with the gas (step S24), and the target 44 is supplied into the chamber 16 through the nozzle hole 124. At this time, the residual gas in the filter 125 causes pressure loss, and a velocity V of the target 44 supplied from the nozzle hole 124 decreases. The velocity V of the target 44 discharged from the nozzle hole 124 is expressed by Expression 1 below, where P is the pressure of the gas in the tank 120, p is the density of the target 44, and Pr is the pressure loss due to the residual gas in the filter 125.

$$\begin{matrix}[ Expression 1 ] & \\ V = \sqrt{\frac{2 ( P - P r )}{ρ}} & ( 1 )\end{matrix}$$

One of the problems to be solved by the present disclosure is to reduce the residual gas in the filter 125 which causes pressure loss in the resupply process and to suppress a decrease in the velocity of the target 44 in the resupply.

### 3. First Embodiment

### 3.1 Configuration

The configuration of the EUV light generation apparatus 12 according to a first embodiment is similar to that of the EUV light generation apparatus 12 shown in FIG. 2.

### 3.2 Operation

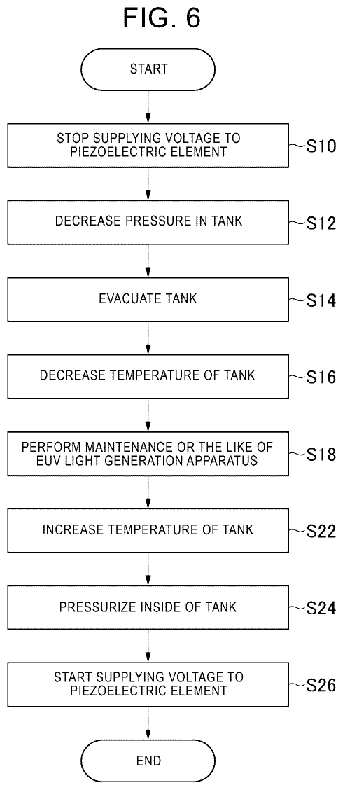

FIG. 6 is a flowchart of the resupply process to which a target supply method according to the first embodiment is applied. The flowchart shown in FIG. 6 will be described in terms of differences from that shown in FIG. 3.

The resupply process shown in FIG. 6 is different from the flowchart of FIG. 3 in that the step of evacuating the tank 120 (step S14) is performed between step S12 and step S16. Further, the resupply process shown in FIG. 6 is different from the flowchart of FIG. 3 in that step S20 is not required because the pressure of vacuum in the tank 120 is maintained during the period from the step S16 to step S22 after step S14.

In step S14 performed after step S12, the EUV processor 40 closes the valve V1 and opens the valve V2. Then, the EUV processor 40 evacuates the tank 120 using the exhaust device 118 to have the pressure of vacuum. The duration of the evacuation is, for example, 30 minutes or more and 3 hours or less. When the pressure in the tank 120 reaches the target pressure of vacuum, the evacuation may be stopped.

The pressure of vacuum in the tank 120 causing expectation of the effect of suppressing decrease in the velocity of the target 44 in the resupply process depends on the filter performance such as the pore size of the filter 125. As the filter performance such as the pore size is improved, the pressure in the tank 120 required to suppress the velocity decrease of the target 44 decreases.

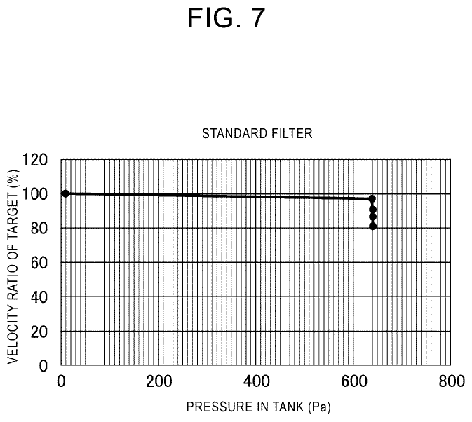

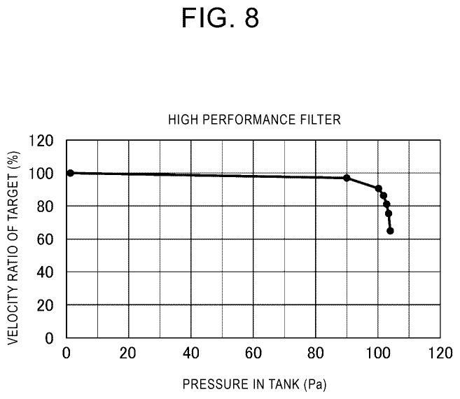

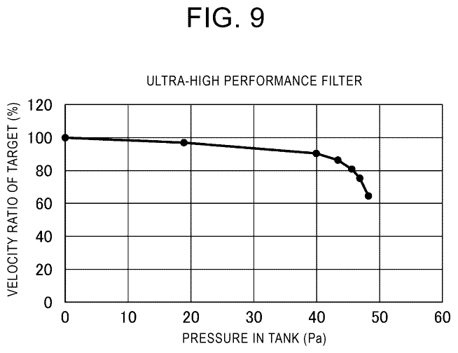

FIGS. 7 to 9 are graphs showing calculation results of the relationship between the pressure in the tank 120 and the velocity ratio of the target 44 when the filter 125 having different filter performance is used. Here, an example in which the filter performance is classified into three types of grades of “standard”, “high performance”, and “ultra-high performance” is shown. FIG. 7 is a graph in which a standard filter is used, FIG. 8 is a graph in which a high performance filter is used, and FIG. 9 is a graph in which an ultra-high performance filter is used. The horizontal axis represents the pressure (Pa) in the tank 120 during evacuation, and the vertical axis represents the velocity ratio of the target 44. The “velocity ratio of the target 44” is a ratio of the velocity of the target 44 at the time of the resupply to the velocity of the target 44 before the supply stops, and can be expressed as a percentage.

A practically acceptable velocity ratio of the target 44 is, for example, 90% or more, and more preferably, 95% or more. According to the graph shown in FIG. 7, the pressure in the tank 120 with which the velocity ratio of the target 44 can be equal to or more than 90% when a standard filter is used is lower than 638 Pa. According to the graph shown in FIG. 8, the pressure in the tank 120 with which the velocity ratio of the target 44 can be equal to or more than 90% when a high performance filter is used is lower than 100 Pa. According to the graph shown in FIG. 9, the pressure in the tank 120 with which the velocity ratio of the target 44 can be equal to or more than 90% when an ultra-high performance filter is used is lower than 40 Pa.

For reducing the residual gas in the tank 120, a lower pressure of vacuum in the tank 120 is preferable. However, in light of the technical goal of suppressing decrease of the velocity of the target 44, it is considered that the necessity to obtain the pressure less than 10⁻⁵ Pa is poor. Therefore, the pressure of vacuum in the tank 120 after evacuation in step S14 is preferably equal to or higher than 10⁻⁵ Pa and lower than 638 Pa, more preferably, equal to or higher than 10⁻⁵ Pa and lower than 100 Pa, and even more preferably, equal to or higher than 10⁻⁵ Pa and lower than 40 Pa.

Thereafter, steps S16, S18, and S22 are performed while the pressure in the tank 120 is maintained at the pressure of vacuum satisfying the above condition. At this time, to maintain the pressure of vacuum in the tank 120, it is preferable to continue the evacuation in processes from step S14 to before step S24 without stopping the evacuation before performing the process in step S16.

Here, even when the evacuation of the tank 120 is stopped after the process in step S14, the evacuation may be stopped at an appropriate timing after step S14 in a case in which the required pressure of vacuum can be maintained until before the process in step S24. When the evacuation in step S14 is stopped before step S24, an airtight structure capable of maintaining the pressure of vacuum satisfying the required pressure condition in the tank 120 even when degassing or the like is performed in the tank 120 is employed. Other steps are similar to those in the flowchart shown in FIG. 3. Steps S10, S14, S16, S22, and S26 are examples of the first, second, third, fourth, and fifth steps in the present disclosure, respectively.

### 3.3 Effect

According to the target supply method of the first embodiment, the tank 120 is evacuated (step S14) to set the pressure to the pressure of vacuum equal to or higher than 10⁻⁵ Pa and lower than 638 Pa, before the temperature of the target 44 is decreased. Therefore, even when the target 44 in the tank 120 is solidified and a gap is formed between the target 44 and the inner surface of the tank 120, the amount of the gas filling the gap is reduced. Thereafter, since the temperature of the tank 120 is increased (step S22) while maintaining the pressure at the pressure of vacuum equal to or higher than 10⁻⁵ Pa and lower than 638 Pa, the gas is not newly filled into the gap.

Therefore, in the resupply process of the first embodiment, the residual gas in the filter 125 that causes the pressure loss can be reduced. Further, the target 44 can also be supplied into the chamber 16 during the resupply of the target 44 at a velocity similar to the supply of the target 44 before the resupply process.

### 4. Second Embodiment

### 4.1 Configuration

The configuration of the EUV light generation apparatus 12 according to a second embodiment is similar to that of the EUV light generation apparatus 12 shown in FIG. 2.

### 4.2 Operation

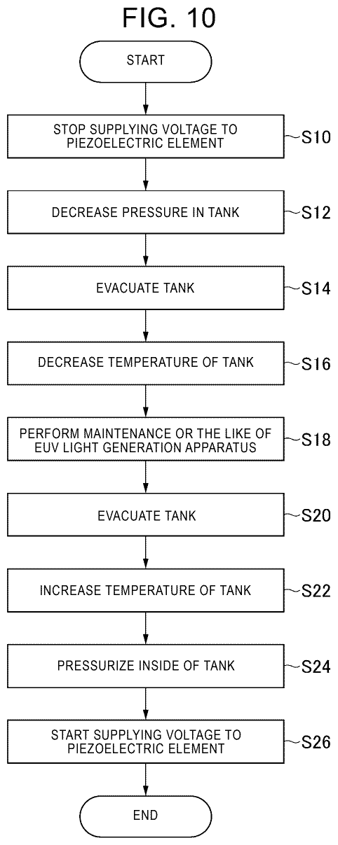

FIG. 10 is a flowchart of the resupply process to which the target supply method according to the second embodiment is applied. The flowchart shown in FIG. 10 will be described in terms of differences from that shown in FIG. 3.

The resupply process shown in FIG. 10 is different from the flowchart of FIG. 3 in that the process of evacuating the tank 120 (step S14) is added between step S12 and step S16. The content of step S14 is as described with reference to FIG. 6.

The evacuation started in step S14 is stopped before the temperature of the tank 120 in step S16 is decreased, before the maintenance in step S18, or the like.

Then, after step S18, the tank 120 is evacuated in step S20 to maintain the pressure inside of the tank 120 at the required pressure of vacuum. Here, the required pressure of vacuum is, as described above, the pressure of vacuum equal to or higher than 10⁻⁵ Pa and lower than 638 Pa, more preferably, equal to or higher than 10⁻⁵ Pa and lower than 100 Pa, and even more preferably, equal to or higher than 10⁻⁵ Pa and lower than 40 Pa. The evacuation of step S20 is stopped before step S24. Other steps may be similar to those in FIG. 3.

### 4.3 Effect

According to the target supply method of the second embodiment, the effects similar to those of the first embodiment can be obtained.

### 5. Third Embodiment

### 5.1 Configuration

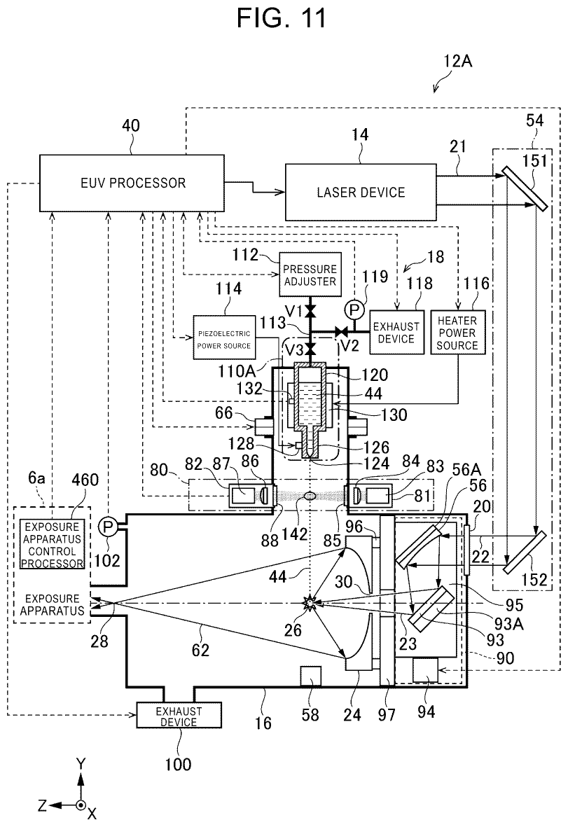

FIG. 11 schematically shows the configuration of an EUV light generation apparatus 12A according to a third embodiment. The configuration shown in FIG. 11 will be described in terms of differences from the configuration shown in FIG. 2.

The EUV light generation apparatus 12A is different from the EUV light generation apparatus 12 in that a valve V3 is arranged between the valve V1 and the tank 120. That is, the EUV light generation apparatus 12A includes a target generator 110A including the valve V3 instead of the target generator 110 shown in FIG. 2. The valve V3 is a valve that seals the inside of the tank 120, and is preferably arranged between the tank 120 and the valve V2. Other configurations may be similar to those in FIG. 2. Here, an exposure apparatus 6a includes an exposure apparatus control processor 460.

### 5.2 Operation

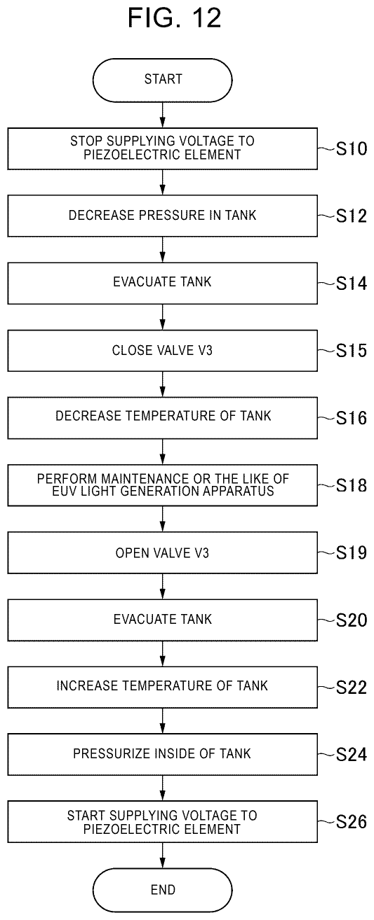

FIG. 12 is a flowchart of the resupply process to which the target supply method according to the third embodiment is applied. The flowchart shown in FIG. 12 will be described in terms of differences from that shown in FIG. 10.

The resupply process shown in FIG. 12 is different from the flowchart of FIG. 10 in that a process of closing the valve V3 (step S15) is added between step S14 and step S16, and a process of opening the valve V3 (step S19) is added between step S18 and step S20. That is, in step S14, the tank 120 is evacuated to the required pressure of vacuum, and then, the valve V3 is closed in step S15, whereby the inside of the tank 120 can be maintained at the pressure of vacuum satisfying the required pressure condition. The evacuation started at step S14 is stopped after the valve V3 is closed.

Thereafter, after step S18, before evacuating the tank 120 in step S20, the EUV processor 40 opens the valve V3 in step S19. Other steps may be similar to those in FIG. 10.

### 5.3 Effect

According to the target supply method of the third embodiment, the effects similar to those of the first embodiment can be obtained.

Further, according to the EUV light generation apparatus 12A of the third embodiment, the pipe line 113 is disconnected upstream of the valve V3, the target generator 110A is removed from the chamber 16, and the target generator 110A can be reattached after maintenance or the like is performed.

### 5.4 Modification

### 5.4.1 Configuration

The EUV light generation apparatus 12A according to a modification of the third embodiment has a similar configuration to the EUV light generation apparatus 12A according to the third embodiment.

### 5.4.2 Operation

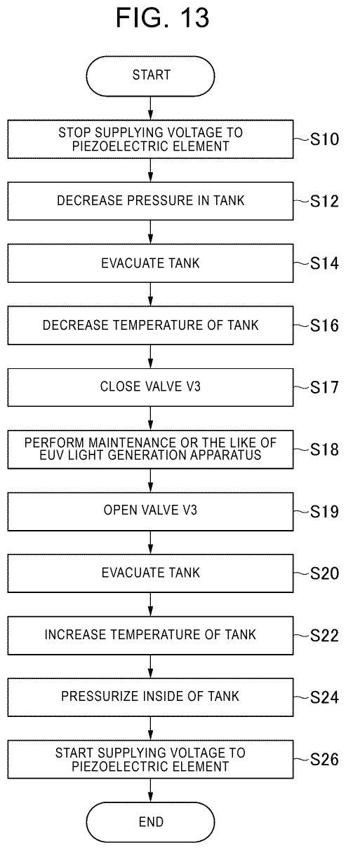

FIG. 13 is a flowchart of the resupply process to which the target supply method according to the modification of the third embodiment is applied. The flowchart shown in FIG. 13 will be described in terms of differences from that shown in FIG. 12.

The resupply process shown in FIG. 13 is different from the flowchart of FIG. 12 in that the process of closing the valve V3 is performed between step S16 and step S18. That is, in the resupply process shown in FIG. 13, instead of step S15 in FIG. 12, step S17 is added between step S16 and step S18, and in step S17, the EUV processor 40 closes the valve V3. The evacuation started at step S14 is stopped after the valve V3 is closed in step S17. Other steps may be similar to those in FIG. 12.

### 5.4.3 Effect

According to the target supply method of the modification of the third embodiment, the effects similar to those of the third embodiment can be obtained.

In the target supply method according to the modification of the third embodiment, the evacuation duration in step S14 becomes longer than that in the target supply method according to the third embodiment, so that the gas remaining in the gap formed in the tank 120 or the filter 125 can be further exhausted. Therefore, the target supply method according to the modification of the third embodiment can further reduce the residual gas causing pressure loss as compared with the target supply method according to the third embodiment.

### 6. Electronic Device Manufacturing Method

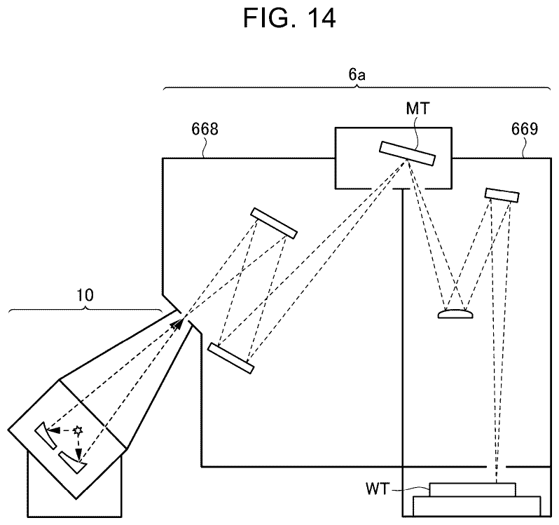

FIG. 14 schematically shows the configuration of the exposure apparatus 6a connected to the EUV light generation system 10. In FIG. 14, the exposure apparatus 6a as the external apparatus 6 includes a mask irradiation unit 668 and a workpiece irradiation unit 669. The mask irradiation unit 668 illuminates, via a reflection optical system, a mask pattern of a mask table MT with the EUV light incident from the EUV light generation system 10. The workpiece irradiation unit 669 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

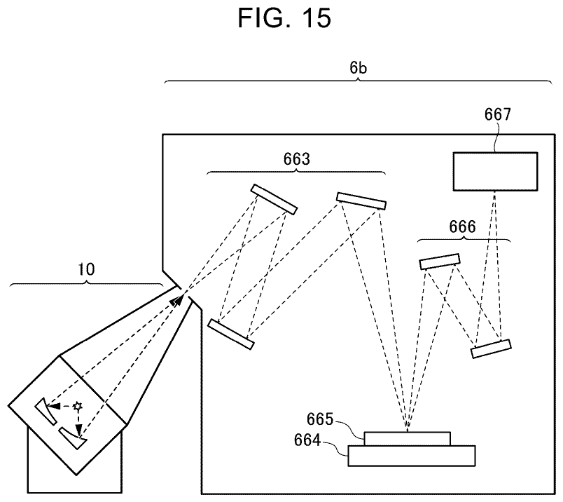

FIG. 15 schematically shows the configuration of an inspection apparatus 6b connected to the EUV light generation system 10. In FIG. 15, the inspection apparatus 6b as the external apparatus 6 includes an illumination optical system 663 and a detection optical system 666. The illumination optical system 663 reflects the EUV light incident from the EUV light generation system 10 to illuminate a mask 665 placed on a mask stage 664. Here, the mask 665 conceptually includes a mask blanks before a pattern is formed. The detection optical system 666 reflects the EUV light from the illuminated mask 665 and forms an image on a light receiving surface of a detector 667. The detector 667 having received the EUV light obtains the image of the mask 665. The detector 667 is, for example, a time delay integration (TDI) camera. Inspection for a defect of the mask 665 is performed based on the image of the mask 665 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a. The EUV light generation system 10 shown in FIGS. 14 and 15 includes the EUV light generation apparatus 12 according to the first or second embodiment, or the EUV light generation apparatus 12A according to the third embodiment.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A target supply method from a target generator into a chamber, the target generator including a tank configured to store a target, a nozzle being in communication with inside the tank and configured to discharge the target in a molten state, and a filter arranged inside the tank or inside the nozzle,
the target supply method comprising:
a first step of stopping supplying the target into the chamber;
a second step of evacuating the tank to set a pressure in the tank to a pressure of vacuum equal to or higher than 10⁻⁵ Pa and lower than 638 Pa;
a third step of decreasing a temperature of the tank to be lower than a melting point of the target while maintaining the pressure of vacuum;
a fourth step of increasing the temperature of the tank to be equal to or higher than the melting point of the target, after the third step, while the pressure of vacuum is maintained; and
a fifth step of resupplying the target, melted in the fourth step, into the chamber.

2. The target supply method according to claim 1,
wherein the pressure of vacuum is equal to or higher than 10⁻⁵ Pa and lower than 100 Pa.

3. The target supply method according to claim 1,
wherein the pressure of vacuum is equal to or higher than 10⁻⁵ Pa and lower than 40 Pa.

4. The target supply method according to claim 1,
wherein the pressure of vacuum in the tank is decreased as performance of the filter is improved.

5. The target supply method according to claim 1,
wherein a duration of the evacuating in the second step is equal to or longer than 30 minutes and equal to or shorter than 3 hours.

6. The target supply method according to claim 1,
wherein, in the third step and the fourth step, the tank is evacuated to maintain the pressure of vacuum.

7. The target supply method according to claim 1,
wherein the evacuating of the tank is stopped before the third step, and
the tank is evacuated between the third step and the fourth step.

8. The target supply method according to claim 1,
wherein the evacuating of the tank is stopped between the third step and the fourth step, and
after the stopping, the tank is evacuated before the fourth step.

9. The target supply method according to claim 1,
wherein the target generator includes a valve for sealing inside of the tank,
the valve is closed between the second step and the third step, and
the valve is opened between the third step and the fourth step to evacuate the tank.

10. The target supply method according to claim 9,
wherein the evacuating is stopped after the valve is closed.

11. The target supply method according to claim 1,
wherein the target generator includes a valve for sealing inside of the tank, and
the valve is closed between the third step and the fourth step, and then, is opened.

12. The target supply method according to claim 11,
wherein the evacuating is stopped after the valve is closed.

13. The target supply method according to claim 11,
wherein the tank is evacuated after the valve is opened, and then, the fourth step is performed while the pressure of vacuum is maintained.

14. The target supply method according to claim 1,
wherein the target is tin, and
the temperature equal to or higher than the melting point is equal to or higher than 250 degrees and equal to or lower than 290 degrees.

15. The target supply method according to claim 1,
wherein the filter is a porous filter.

16. An electronic device manufacturing method, comprising:
generating extreme ultraviolet light by irradiating a target, resupplied into a chamber, with pulse laser light, using an extreme ultraviolet light system;
outputting the extreme ultraviolet light to an exposure apparatus; and
exposing a photosensitive substrate to the extreme ultraviolet light in the exposure apparatus to manufacture an electronic device,
the extreme ultraviolet light system including:
the chamber;
a target generator configured to supply the target into the chamber; and
a laser device configured to output the pulse laser light,
the target generator including:
a tank configured to store the target;
a nozzle being in communication with inside the tank and configured to discharge the target in a molten state; and
a filter arranged inside the tank or inside the nozzle, and
the target being resupplied into the chamber through steps of:
stopping supplying the target into the chamber;
evacuating the tank to set a pressure in the tank to a pressure of vacuum equal to or higher than 10⁻⁵ Pa and lower than 638 Pa;
decreasing a temperature of the tank to be lower than a melting point of the target while maintaining the pressure of vacuum;
increasing the temperature of the tank to be equal to or higher than the melting point of the target, after the temperature decreasing, while the pressure of vacuum is maintained; and
resupplying the target, melted with the temperature increasing, into the chamber.

17. An electronic device manufacturing method, comprising:
generating extreme ultraviolet light by irradiating a target, resupplied into a chamber, with pulse laser light;
inspecting a defect of a mask by irradiating the mask with the extreme ultraviolet light;
selecting a mask using a result of the inspection; and
exposing and transferring a pattern formed on the selected mask onto a photosensitive substrate, the extreme ultraviolet light system including:
the chamber;
a target generator configured to supply the target into the chamber; and
a laser device configured to output the pulse laser light,
the target generator including:
a tank configured to store the target;
a nozzle being in communication with inside the tank and configured to discharge the target in a molten state; and
a filter arranged inside the tank or inside the nozzle, and
the target being resupplied into the chamber through steps of:
stopping supplying the target into the chamber;
evacuating the tank to set a pressure in the tank to a pressure of vacuum equal to or higher than 10⁻⁵ Pa and lower than 638 Pa;
decreasing a temperature of the tank to be lower than a melting point of the target while maintaining the pressure of vacuum;
increasing the temperature of the tank to be equal to or higher than the melting point of the target, after the temperature decreasing, while the pressure of vacuum is maintained; and
resupplying the target, melted with the temperature increasing, into the chamber.
